(19) United States
(12) Patent Application Publication
(10) Pub. No.: US 2012/0240988 A1
(43) Pub. Date: Sep. 27, 2012

(54) PHOTOVOLTAIC CELL MODULE

(75) Inventors: Hsin-Rong Tseng, Tainan City (TW); Chun-Liang Lin, New Taipei City (TW)

(73) Assignee: AU OPTRONICS CORPORATION, Hsinchu (TW)

(21) Appl. No.: 13/191,517

(22) Filed: Jul. 27, 2011

(30) Foreign Application Priority Data
Mar. 25, 2011 (TW) 100110399

(51) Int. Cl. H01L 31/06; H01L 31/055

(52) U.S. Cl. 136/255

(57) ABSTRACT

A photovoltaic cell module includes a substrate, a first photovoltaic cell and a second photovoltaic cell. The substrate has a light conversion layer thereon, and the light conversion layer converts light having wavelength ranges from 300 nm to 500 nm to light having wavelength ranges from 500 nm to 700 nm. The first photovoltaic cell is disposed on a surface of the substrate and the second photovoltaic cell is disposed on another surface of the substrate.

### CROSS-REFERENCE TO RELATED APPLICATION

This application claims the priority benefit of Taiwan application serial no. 100110399, filed on Mar. 25, 2011. The entirety of the above-mentioned patent application is hereby incorporated by reference herein and made a part of this specification.

### BACKGROUND OF THE INVENTION

1. Field of the Invention

The invention relates to a photovoltaic cell module and more particularly to an organic photovoltaic (OPV) cell module.

2. Description of Related Art

With the consideration of environmental protection in recent years, the developments of alternative energy and renewable energy have become popular in response to the shortage of fossil energy and to reduce the impact on environment caused by the use of fossil energy. Herein, photovoltaic cells attract the most attention among the alternative energy and renewable energy. Photovoltaic cells are capable of converting solar energy into electric energy directly without polluting the environment by generating hazardous substances such as carbon dioxide or nitride in the power generation process.

Conventionally, a first electrode layer, an active layer, and a second electrode layer are formed on a substrate in a traditional photovoltaic cell. When a light beam irradiates the photovoltaic cell, the active layer generates free electron-hole pairs under the effect of light energy. Moreover, the electrons and the holes move toward two electrode layers respectively through an electric field between the two electrode layers so as to generate a storage state of electric energy. When a load circuit or an electronic device is disposed additionally, electric energy can be provided to drive the circuit or the device.

However, the main problem of photovoltaic cells is the limitation in light absorption rate or electric energy output power. Therefore, the enhancement in light absorption rate and output power of photovoltaic cells has been developed extensively.

### SUMMARY OF THE INVENTION

Accordingly, a photovoltaic cell module is introduced herein, wherein the light absorption efficiency of the photovoltaic cell is enhanced to improve the overall efficiency of the photovoltaic cell module.

A photovoltaic cell module includes a substrate, a first photovoltaic cell and a second photovoltaic cell is provided. The substrate has a light conversion layer thereon, and the light conversion layer converts light having wavelength ranges from 300 nm to 500 nm to light having wavelength ranges from 500 nm to 700 nm. The first photovoltaic cell is disposed on a surface of the substrate and the second photovoltaic cell is disposed on another surface of the substrate.

In light of the foregoing, the light conversion layer is disposed between the first photovoltaic cell and the second photovoltaic cell so as to convert the light having wavelength ranges from 300 nm to 500 nm to the light having wavelength ranges from 500 nm to 700 nm. Since the light (300 nm to 500 nm) which may not be absorbed by the photovoltaic cells is changed into the light (500 nm to 700 nm) that can be absorbed by the photovoltaic cells, the overall efficiency of the photovoltaic cell module is enhanced.

In order to make the aforementioned and other features and advantages of the present invention more comprehensible, several embodiments accompanied with figures are described in detail below.

### BRIEF DESCRIPTION OF THE DRAWINGS

The accompanying drawings constituting a part of this specification are incorporated herein to provide a further understanding of the invention. Here, the drawings illustrate embodiments of the invention and, together with the description, serve to explain the principles of the invention.

FIG. 1 is a schematic cross-sectional view of a photovoltaic cell module according to one exemplary embodiment.

FIG. 2 is a curve diagram of a light absorption wave band of a photovoltaic cell module according to one exemplary embodiment.

FIG. 3 is a schematic cross-sectional view showing light absorption of the photovoltaic cell module of FIG. 1.

FIG. 4 is a curve diagram showing the light having wavelength ranges from 300 nm to 500 nm is converted to the light having wavelength ranges from 500 nm to 700 nm by the light conversion layer of the photovoltaic cell module in FIG. 1.

FIG. 5 is a curve diagram showing the light absorption rate (absorbability) and the light wavelength of the photovoltaic cell module in FIG. 1.

FIG. 6 and FIG. 7 are schematic cross-sectional views respectively showing a photovoltaic cell module according to one exemplary embodiment.

FIG. 8 and FIG. 9 are schematic cross-sectional views respectively showing a connection between the first photovoltaic cell and the second photovoltaic cell in a photovoltaic cell module.

### DESCRIPTION OF EMBODIMENTS

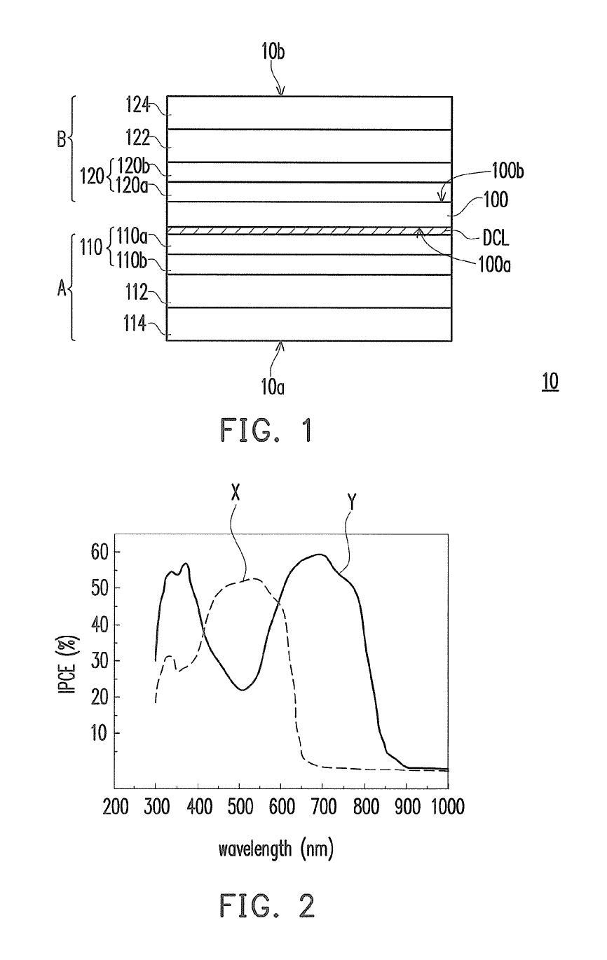

FIG. 1 is a schematic cross-sectional view of a photovoltaic cell module according to one exemplary embodiment. Referring to FIG. 1, the photovoltaic cell module 10 of this exemplary embodiment includes a substrate 100, a first photovoltaic cell A and a second photovoltaic cell B, and the substrate 100 has a light conversion layer DCL thereon. In addition, the photovoltaic cell module 10 has a light incident surface 10a and a light reflective surface 10b.

The substrate 100 includes a surface 100a and another surface 100b opposite to the surface 100a. The substrate 100 may be a hard material substrate (such as, a glass substrate, a silicon substrate) or a flexible substrate (such as an organic polymer substrate). The substrate 100 is preferably a flexible substrate. If the substrate 100 is a hard substrate, the photovoltaic cell module 10 may be fabricated using the roll-to-roll process.

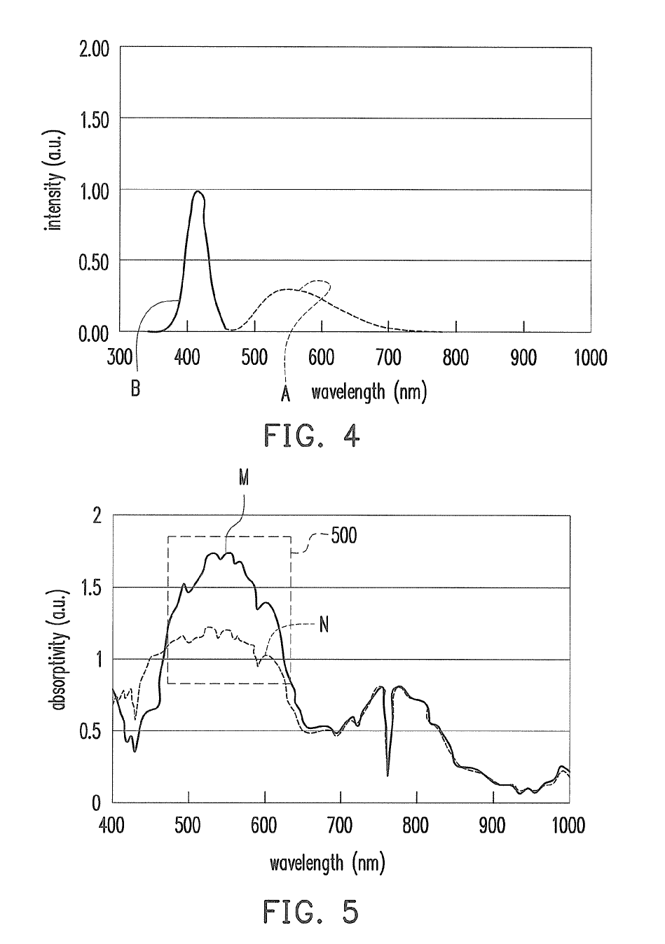

According to the embodiment, the light conversion layer DCL is disposed on the surface 100a of the substrate 100. The light conversion layer DCL converts light having wavelength ranges from 300 nm to 500 nm to light having wavelength ranges from 500 nm to 700 nm. As shown in FIG. 4, the light conversion layer DCL converts the light with light band (such as curve B) into the light with light band (such as curve A). The light conversion layer DCL comprises a fluorescence material or a phosphorescence material.

The first photovoltaic cell A is disposed on the surface 100a of the substrate 100 and includes a first electrode layer 110, a first active layer 112, and a second electrode layer 114. In the embodiment, the light conversion layer DCL is disposed between the first photovoltaic cell A and the substrate 100.

The first electrode layer 110 of the first photovoltaic cell A is disposed on the surface 100a of the substrate 100. According to an exemplary embodiment of the disclosure, the first electrode layer 110 includes a transparent electrode material. In one exemplary embodiment, the first electrode layer 110 includes a transparent conductive layer 110a and a work function adjustment layer 110b. The transparent conductive layer 110a in this exemplary embodiment includes indium tin oxide, indium zinc oxide, aluminum tin oxide, aluminum zinc oxide, indium germanium zinc oxide or other appropriate metal oxides. The work function adjustment layer 110b serves to provide the first electrode layer 110 to have a more appropriate work function relative to the first active layer 112. The material of the work function adjustment layer 110b includes, for example, cesium carbonate (CsCO₃), zinc oxide (ZnO), or other appropriate work function adjustment materials.

The first active layer 112 of the first photovoltaic cell A covers the first electrode layer 110. The first active layer 112 absorbs the light of a first wavelength range. According to an exemplary embodiment, the first active layer 112 is constituted with an organic light absorption material and mainly absorbs the light with visible light band or the light with infrared light band. If the first active layer 112 absorbs the light with the visible light band, the material of the first active layer 112 may include, for example, (poly(3-hexylthiophene): [6,6]-phenyl-C61-butyric acid methyl ester (P3HT [60]PCBM)), (poly[2-methoxy-5-(30,70-dimethyloctyloxy)-1,4-phenylenevinylene]: [6,6]-phenyl-C61-butyricacidmethyl ester (MDMO-PPV:[60]PCBM)), or other appropriate materials. If the first active layer 112 absorbs the light with the infrared light band, the material of the first active layer 112 may include, for example, (poly[2,6-(4,4-bis-(2-ethylhexyl)-4H-cyclopenta[2,1-b;3,4-b′]dithiophene)-alt-4,7-(2,1,3-benzothiadiazole)]: [6,6]-phenyl-C71 butyric acid methyl ester (PCPDTBT: [70]PCBM)), (poly[4,8-bis-substituted-benzo[1,2-b:4,5-b′]dithiophene-2,6-diyl-alt-4-substituted-thieno[3,4-b]thio-phene-2,6-diyl]: [6,6]-phenyl-C 71 butyric acid methyl ester (PBDTTT:[70]PCBM)), or other appropriate materials.

The second electrode layer 114 of the first photovoltaic cell A covers the first active layer 112. According to an exemplary embodiment, the second electrode layer 114 includes, for example, a transparent electrode material, such as an organic conductive material. Generally speaking, the material of the second electrode layer 114 is selected based on the consideration of its work function and its compatibility with the first active layer 112. Hence, the material of the second electrode layer 114 may include Poly(3,4-ethylenedioxythiophene)poly(styrenesulfonate) (PEDOT:PPS), indium titanium oxide, or other appropriate materials.

The second photovoltaic cell B is disposed on another surface 100b of the substrate 100 and electrically connected to the first photovoltaic cell A. The second photovoltaic cell B includes a third electrode layer 120, a second active layer 122, and a fourth electrode layer 124.

The third electrode layer 120 of the second photovoltaic cell B is disposed on the second surface 100b of the substrate 100. According to an exemplary embodiment, the third electrode layer 120 includes a transparent electrode material. In one exemplary embodiment, the third electrode layer 120 includes a transparent conductive layer 120a and a work function adjustment layer 120b. In this exemplary embodiment, the material of the transparent conductive layer 120a includes, for example, indium tin oxide, indium zinc oxide, aluminum tin oxide, aluminum zinc oxide, indium germanium zinc oxide, or other appropriate metal oxides. The work function adjustment layer 120b serves to provide the third electrode layer 120 to have a more appropriate work function relative to the second active layer 122. The material of the work function adjustment layer 110b includes, for example, PEDOT:PPS, molybdenum oxide, or other work function adjustment materials.

The second active layer 122 of the second photovoltaic cell B covers the third electrode layer 120. The second active layer 122 absorbs the light of a second wavelength range. According to an exemplary embodiment, the second active layer 122 is, for example, an organic light absorption material and mainly absorbs the light with the infrared light band and the light with the visible light band. If the second active layer 122 absorbs the light with the visible light band, the material of the second active layer 122 includes, for example, (poly(3-hexylthiophene): [6,6]-phenyl-C61-butyric acid methyl ester (P3HT:[60]PCBM)), (poly[2-methoxy-5-(30,70-dimethyloctyloxy)-1,4-phenylenevinylene]: [6,6]-phenyl-C61-butyricacidmethyl ester (MDMO-PPV:[60]PCBM)), or other appropriate materials. If the first active layer 112 absorbs light with the infrared red light band, the material of the first active layer 112 may include, for example, (poly[2,6-(4,4-bis-(2-ethylhexyl)-4H-cyclopenta [2,1-b;3,4-b]dithiophene)-alt-4,7-(2,1,3-benzothiadiazole)]:[6,6]-phenyl-C71 butyric acid methyl ester (PCPDTBT: [70]PCBM)), (poly[4,8-bis-substituted-benzo[1,2-b:4,5-b′]dithiophene-2,6-diyl-alt-4-substituted-thieno[3,4-b]thio-phene-2,6-diyl]:[6,6]-phenyl-C71 butyric acid methyl ester (PBDTTT:[70]PCBM)), or other appropriate materials.

It is worthy to note that, the second active layer 122 of the second photovoltaic cell B and the first active layer 112 of the first photovoltaic cell A absorb light of different wavelength ranges. As shown in FIG. 2, the y-axis represents the incident photon conversion efficiency (IPCE (%)), while the x-axis represents the wavelength. If the first active layer 112 of the photovoltaic cell A absorbs the light of the visible light band (such as curve X), the second active layer 122 of the second photovoltaic cell B absorbs light of the infrared light band (such as curve Y). In contrast, if the first active layer 112 of the first photovoltaic cell A absorbs the light of the infrared light band (such as curve Y), the second active layer 122 of the second photovoltaic cell B absorbs the light of the visible light band (such as curve X).

Moreover, the fourth electrode layer 124 of the second photovoltaic cell B covers the second active layer 122. According to an exemplary embodiment, the forth electrode layer 124 includes, for example, a reflective electrode material. In another exemplary embodiment, the fourth electrode layer 124 includes high conductivity and high reflective metal material, such as aluminum, silver, or other alloys.

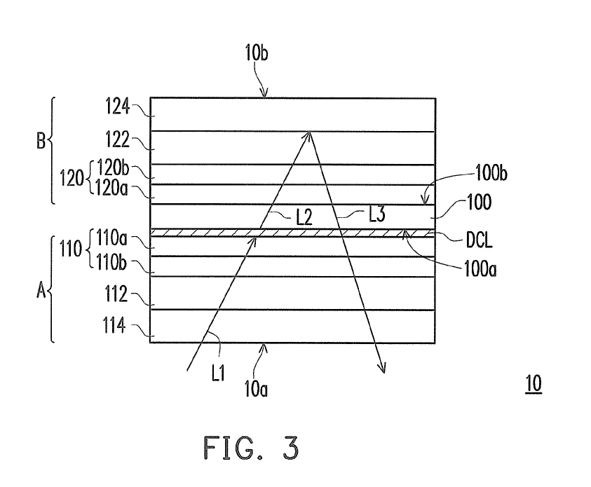

In the above photovoltaic cell module 10, the surface of the second electrode layer 114 of the first photovoltaic cell A may serve as the light incident surface 10a of the photovoltaic cell module 10, while the surface of the fourth electrode layer 124 of the second photovoltaic cell B may serve as a light reflective surface 10b of the photovoltaic cell module 10. As shown in FIG. 3, when external light L1 enters the photovoltaic cell module 10 through the light incident surface 100a, the light with the first wavelength range (such as the infrared light band) is absorbed when passing through the first active layer 112.

When the light L1 arrives at the light conversion layer DCL, light having wavelength ranges from 300 nm to 500 nm is converted to light having wavelength ranges from 500 nm to 700 nm. As shown in FIG. 4, the light conversion layer DCL converts the light with light band (such as curve B) into the light with light band (such as curve A). In other words, the light L2 with wavelength ranges from 300 nm to 500 nm (the ultraviolet light band) has been converted to have wavelength ranges from 500 nm to 700 nm (the infrared light band and the visible light band). After the light L2 passes through the substrate 100 and arrives in the second active layer 122, the light with the second wavelength range (such as the visible light band) is absorbed by the second active layer 122.

Thereafter, when the light L2 arrives at the fourth electrode layer 124, the light L2 is reflected by the fourth electrode layer 124 to form light L3. The reflected light L3 with the second wavelength range (such as the visible light band) is absorbed again when passing through the second active layer 122. Then, when the light L3 passes through the substrate 100 and enters the first active layer 112, the light L3 with the first wavelength range (such as the infrared light band) is also absorbed again by the first active layer 112.

According to an exemplary embodiment, the light with the first wavelength range (such as the infrared light band) and light with the second wavelength range (such as the visible light band) of the external light are respectively absorbed by the first active layer 112 and the second active layer 122. In addition, when the external light passes through the light conversion layer DCL, the external light with wavelength ranges from 300 nm to 500 nm (can not be absorbed by the first and second active layers) is converted to be light having wavelength ranges from 500 nm to 700 nm (can be absorbed by the first and second active layers). Because the first photovoltaic cell A and the second photovoltaic cell B are respectively disposed on two surfaces 100a, 100b of the substrate 100 and the light conversion layer DCL is disposed between the first photovoltaic cell A and the second photovoltaic cell B, the overall efficiency of the photovoltaic cell module is enhanced.

FIG. 5 is a curve diagram showing the light absorption rate (absorbability) and the light wavelength of the photovoltaic cell module in FIG. 1. As shown in FIG. 5, the curve M represents the absorption curve of the photovoltaic cell module with a light conversion layer disposed therein, and the curve N represents the absorption curve of the photovoltaic cell module without a light conversion layer disposed therein. Referring to FIG. 5, the optical absorption rate in the visible light region (region 500) is higher for curve M than for curve N, and the quantum transforming efficiency is increased by about 85%. Accordingly, configuring a light conversion layer in a photovoltaic cell module may actually enhance the overall efficiency of the photovoltaic cell module.

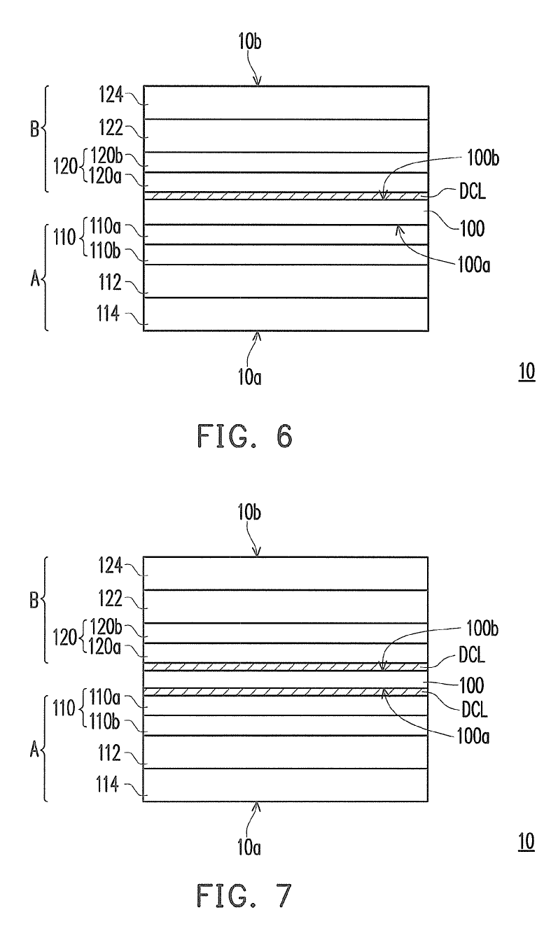

FIG. 6 is a schematic cross-sectional view showing a photovoltaic cell module according to one exemplary embodiment. The embodiment shown in FIG. 6 is similar to the embodiment shown in FIG. 1 so that components identical to those of FIG. 1 will be denoted with the same numerals in FIG. 6 and not repeated herein. In the embodiment of FIG. 6, the light conversion layer DCL is disposed on the surface 100b of the substrate 100. Therefore, the light conversion layer DCL is disposed between the second photovoltaic cell B and the substrate 100.

In the embodiment, the light conversion layer DCL is disposed between the second photovoltaic cell B and the first photovoltaic cell A, and when the external light passes through the light conversion layer DCL, light with wavelength ranges from 300 nm to 500 nm (can not be absorbed by the first and second active layers) is converted to be light having wavelength ranges from 500 nm to 700 nm (can be absorbed by the first and second active layers). Therefore, the overall efficiency of the photovoltaic cell module is enhanced by disposing the light conversion layer DCL between the first photovoltaic cell A and the second photovoltaic cell B.

FIG. 7 is a schematic cross-sectional view showing a photovoltaic cell module according to one exemplary embodiment. The embodiment shown in FIG. 7 is similar to the embodiment shown in FIG. 1 so that components identical to those of FIG. 1 will be denoted with the same numerals in FIG. 7 and not repeated herein. In the embodiment of FIG. 7, the light conversion layer DCL is disposed on the surface 100a and the surface 100b of the substrate 100. Therefore, the light conversion layer DCL is disposed between the first photovoltaic cell A and the substrate 100 and between the second photovoltaic cell B and the substrate 100.

Similarly, since the light conversion layer DCL is disposed between the second photovoltaic cell B and the first photovoltaic cell A, the light with wavelength ranges from 300 nm to 500 nm (can not be absorbed by the first and second active layers) is converted to be light having wavelength ranges from 500 nm to 700 nm (can be absorbed by the first and second active layers) when the external light passes through the light conversion layer DCL. Therefore, the overall efficiency of the photovoltaic cell module is enhanced through disposing the light conversion layer DCL between the first photovoltaic cell A and the second photovoltaic cell B.

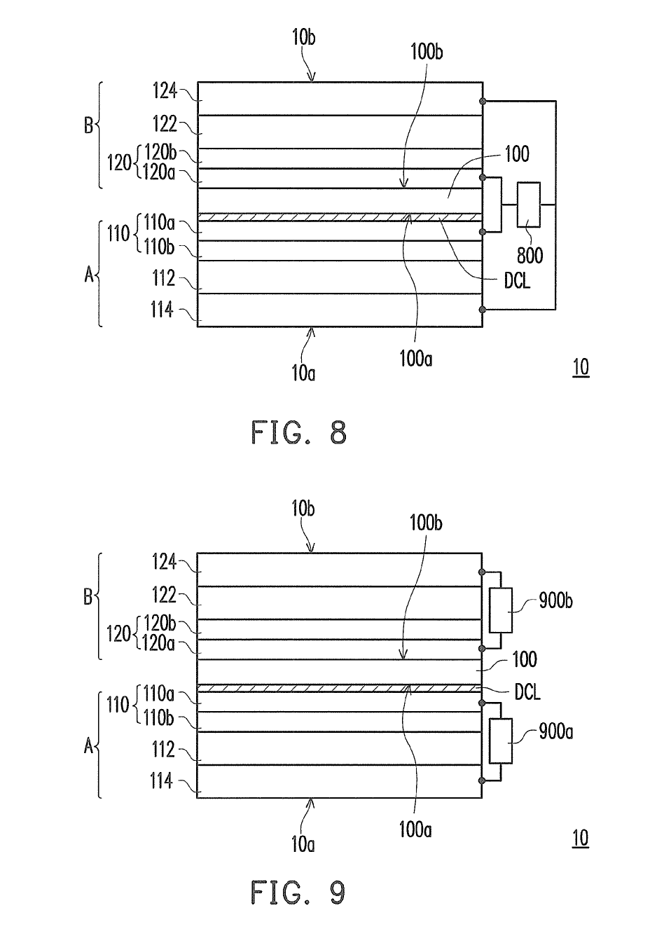

In the embodiments of FIG. 1, FIG. 6 and FIG. 7, the first photovoltaic cell A and the second photovoltaic cell B are electrically connected to each other. The first photovoltaic cell A and the second photovoltaic cell B can be electrically connected in series (series connection) or in parallel (parallel connection), as shown in FIG. 8 and FIG. 9.

As shown in FIG. 8, in the embodiment, the configuration of the photovoltaic cell module is similar or the same to FIG. 1. According to the embodiment, the first photovoltaic cell A and the second photovoltaic cell B are electrically connected in series (series connection). For example, the first electrode layer 114 of the first photovoltaic cell A is electrically connected to the fourth electrode 124 of the second photovoltaic cell B. That is, the first electrode layer 114 and the fourth electrode 124 are electrically connected to one terminal of an output unit 800. The second electrode layer 110 of the first photovoltaic cell A is electrically connected to the third electrode 120 of the second photovoltaic cell B. That is, the second electrode layer 110 and the third electrode 120 are electrically connected to another terminal of the output unit 800.

The first electrode layer 114 of the first photovoltaic cell A and the fourth electrode 124 of the second photovoltaic cell B can be electrically connected to each other with an external circuit board (not shown). The second electrode layer 110 of the first photovoltaic cell A and the third electrode 120 of the second photovoltaic cell B can be electrically connected to each other with an external circuit board (not shown) or a conductive structure (not shown) disposed in the substrate 100.

As shown in FIG. 9, in the embodiment, the configuration of the photovoltaic cell module is similar or the same to FIG. 1. According to the embodiment, the first photovoltaic cell A and the second photovoltaic cell B are electrically connected in parallel (parallel connection). For example, the first electrode layer 114 of the first photovoltaic cell A and the fourth electrode 124 of the second photovoltaic cell B are electrically connected to an output unit 900a, while the second electrode layer 110 of the first photovoltaic cell A and the third electrode 120 of the second photovoltaic cell B are electrically connected to another output unit 900b. That is, the energy generated from the first photovoltaic cell A and the second photovoltaic cell B is respectively output to the corresponding output units 900a and 900b.

Even though the connections of the first photovoltaic cell A and the second photovoltaic cell B shown in FIG. 8 and FIG. 9 are described with the photovoltaic cell module of FIG. 1, one skilled in the art may understand the connection of the first photovoltaic cell A and the second photovoltaic cell B of the photovoltaic cell modules of FIG. 6 and FIG. 7 according to the above description. In other word, the first photovoltaic cell A and the second photovoltaic cell B of the photovoltaic cell modules of FIG. 6 and FIG. 7 may be electrically connected to each other in series (series connection) or in parallel (parallel connection).

In light of the foregoing, the light conversion layer is disposed between the first photovoltaic cell and the second photovoltaic cell so as to convert the light having wavelength ranges from 300 nm to 500 nm to the light having wavelength ranges from 500 nm to 700 nm. Since the light (300 nm to 500 nm) which may not be absorbed by the photovoltaic cells is changed into the light (500 nm to 700 nm) that can be absorbed by the photovoltaic cells, the overall efficiency of the photovoltaic cell module is enhanced.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A photovoltaic cell module, comprising:
a substrate, having a light conversion layer thereon, wherein the light conversion layer converts light having wavelength ranges from 300 nm to 500 nm to light having wavelength ranges from 500 nm to 700 nm;
a first photovoltaic cell, disposed on a surface of the substrate; and
a second photovoltaic cell, disposed on another surface of the substrate, and the second photovoltaic cell is electrically connected to the first photovoltaic cell.

2. The photovoltaic cell module as claimed in claim 1, wherein the light conversion layer comprises a fluorescence material or a phosphorescence material.

3. The photovoltaic cell module as claimed in claim 1, wherein the light conversion layer is disposed between the first photovoltaic cell and the substrate.

4. The photovoltaic cell module as claimed in claim 1, wherein the light conversion layer is disposed between the second photovoltaic cell and the substrate.

5. The photovoltaic cell module as claimed in claim 1, wherein the light conversion layer is disposed between the first photovoltaic cell and the substrate and between the second photovoltaic cell and the substrate.

6. The photovoltaic cell module as claimed in claim 1, wherein the first photovoltaic cell and the second photovoltaic cell are electrically connected in series.

7. The photovoltaic cell module as claimed in claim 1, wherein the first photovoltaic cell and the second photovoltaic cell are electrically connected in parallel.

8. The photovoltaic cell module as claimed in claim 1, wherein the first photovoltaic cell comprises a first electrode layer, a second electrode layer and a first active layer between the first electrode layer and the second electrode layer.

9. The photovoltaic cell module as claimed in claim 8, wherein the second photovoltaic cell comprises a third electrode layer, a fourth electrode layer and a second active layer between the third electrode layer and the fourth electrode layer.

10. The photovoltaic cell module as claimed in claim 9, wherein the first active layer and the second active layer comprises an organic light absorption material, respectively.

11. The photovoltaic cell module as claimed in claim 9, wherein one of the first active layer and the second active layer absorbs visible light, while another of the first active layer and the second active layer absorbs infrared light.

12. The photovoltaic cell module of claim 9, wherein the first electrode layer, the second electrode layer, and the third electrode layer comprise a transparent electrode material respectively.

13. The photovoltaic cell module of claim 9, wherein the fourth electrode layer comprises a reflective electrode material.
